(19) United States
(12) Patent Application Publication
(10) Pub. No.: US 2010/0269898 A1
(43) Pub. Date: Oct. 28, 2010

(54) METHOD FOR MANUFACTURING PHOTOVOLTAIC CELL AND PHOTOVOLTAIC CELL

(75) Inventors: Hirohisa Takahashi, Sanmu-shi (JP); Satoru Ishibashi, Sanmu-shi (JP)

Correspondence Address: GROSSMAN, TUCKER, PERREAULT & PFLEGER, PLLC, 55 SOUTH COMMERICAL STREET, MANCHESTER, NH, 03101, US

(73) Assignee: ULVAC, INC., Chigasaki-shi (JP)

(21) Appl. No.: 12/810,060

(22) PCT Filed: Dec. 24, 2008
(86) PCT No.: PCT/JP2008/073399

§ 371 Date: Jun. 22, 2010

(30) Foreign Application Priority Data
Dec. 28, 2007 (JP) P2007-339534

(51) Int. Cl. H01L 31/02; H01L 31/18

(52) U.S. Cl. 136/255; 438/98; 257/E31.124

(57) ABSTRACT

A method for manufacturing a photovoltaic cell that is provided with an upper electrode that is arranged on the light incoming side and functions as a power extraction electrode, the method including the step of: forming the upper electrode on a substrate by sputtering using a target that contains a zinc oxide-based material, wherein in the step of forming the upper electrode, the sputtering is performed in an atmosphere that contains two or three selected from a group consisting of hydrogen gas, oxygen gas, and water vapor.

### TECHNICAL FIELD

The present invention relates to a method for manufacturing a photovoltaic cell, and specifically to a method for a manufacturing transparent electrically conductive film that is used as an upper electrode and an intermediate electrode of a photovoltaic cell.

Priority is claimed on Japanese Patent Application No. 2007-339534, filed Dec. 28, 2007, the content of which is incorporated herein by reference.

### BACKGROUND ART

Conventionally, as a material of a transparent electrically conductive film that forms an upper electrode and an intermediate electrode of a photovoltaic cell, indium tin oxide (In₂O₃—SnO₂) has been utilized. However, indium (In), which is the raw material of ITO, is a rare metal, and is expected in the future to increase in cost as it comes to be harder to obtain. Therefore, zinc oxide (ZnO)-based materials, which are abundant and inexpensive, are attracting attention as a material for a transparent electrically conductive film in place of ITO (for example, refer to Patent Document 1). ZnO-based materials are suited to sputtering in which uniform film formation over a large substrate is possible. By changing a target composed of an In₂O₃-based material such as ITO to a target composed of a ZnO-based material in a film forming apparatus, film formation is possible. In addition, since a ZnO-based material does not include highly insulating low-grade oxides (InO) such as In₂O₃-based materials, anomalies in sputtering hardly occur.

[Patent Document 1] Japanese Unexamined Patent Application, First Publication No. H09-87833

### DISCLOSURE OF THE INVENTION

### Problems to be Solved by the Invention

Although the transparency of a conventional transparent electrically conductive film composed of a ZnO-based material that forms an upper electrode and an intermediate electrode of a photovoltaic cell compares favorably with a conventional ITO film, there is the problem of its surface resistance being higher than an ITO film. Therefore, in order to lower the surface resistance of a transparent electrically conductive film composed of a ZnO-based material to the desired value, a method has been proposed that consists of introducing hydrogen gas as a reducing gas to the chamber during sputtering, and performing film formation in this reducing gas atmosphere.

However, in this case, although the surface resistance of the obtained transparent electrically conductive film does indeed decrease, a slight amount of metallic luster is produced on the surface thereof. For that reason, the problem arises of the transmittance thereof decreasing, and the photoelectric conversion efficiency of the photovoltaic cell decreasing.

The present invention was achieved in order to solve the abovementioned issues, and has as its object to provide a manufacturing method for a photovoltaic cell that lowers the surface resistance of a transparent electrically conductive film that is formed using a zinc oxide-based material and constitutes the upper electrode and intermediate electrode of a photovoltaic cell, favorably maintains transmittance of visible light rays, and improves the photoelectric conversion efficiency.

### Means for Solving the Problem

In order to solve the aforementioned issues, the present invention employs the following.

That is, a method for manufacturing a photovoltaic cell according to the first aspect of the present invention is a method for manufacturing a photovoltaic cell that is provided with an upper electrode that is arranged on the light incoming side and functions as a power extraction electrode, the method including the step of: forming the upper electrode on a substrate by sputtering using a target that contains a zinc oxide-based material, wherein in the step of forming the upper electrode, the sputtering is performed in an atmosphere that contains two or three selected from a group consisting of hydrogen gas, oxygen gas, and water vapor.

It may be arranged such that, in the case of including at least the hydrogen gas and the oxygen gas in the atmosphere when performing the sputtering, a ratio R (P_{H2}/P_{O2}) of the partial pressure of the hydrogen gas (P_{H2}) to the partial pressure of the oxygen gas (P_{O2}) satisfies Equation (1) below.

R=P_{H2}/P_{O2}≧2 (1)

In this case, it is possible to obtain a transparent electrically conductive film with a specific resistance of 2,000 μΩ·cm or less.

It may be arranged such that the sputtering voltage that is applied to the target is 340 V or less when performing the sputtering.

In this case, since it is possible to form a zinc oxide-based transparent electrically conductive film in which the crystal lattice is organized by lowering the discharge voltage, it is possible to obtain a transparent electrically conductive film in which the specific resistance is low.

It may be arranged such that a sputtering voltage composed of a high frequency voltage superimposed on a direct current voltage is applied to the target when performing the sputtering.

In this case, since a sputtering voltage is used in which a high-frequency voltage is superimposed on a direct current voltage, it is possible to further lower the discharge voltage.

It may be arranged such that the maximum value of the strength of the horizontal magnetic field at the surface of the target when performing the sputtering is 600 Gauss or more.

Since the maximum value of the strength of the horizontal magnetic field is 600 Gauss or more, it is possible to lower the discharge voltage.

It may be arranged such that the zinc oxide-based material is aluminum-doped zinc oxide or gallium-doped zinc oxide.

A method for manufacturing a photovoltaic cell according to the second aspect of the present invention is a method for manufacturing a tandem-type photovoltaic cell in which an upper electrode, a first electricity generating layer, an intermediate electrode, a second electricity generating layer, and a rear electrode are laminated on a substrate, the method including the step of: forming the upper electrode and the intermediate electrode by sputtering using a target that contains a zinc oxide-based material, wherein in the step of forming the upper electrode and the intermediate electrode, the sputtering is performed in an atmosphere in which at least one of hydrogen gas and water vapor, and oxygen gas are introduced; and the introduction amount of the oxygen gas when forming the intermediate electrode is made more than the introduction amount of the oxygen gas when forming the upper electrode.

According to the second aspect of the aforementioned present invention, the upper electrode and the intermediate electrode are obtained in which the amount of oxygen atoms that are contained in the upper electrode and the intermediate electrode are suitably controlled. Accordingly, it is possible to obtain a photovoltaic cell that, in addition to the effect that is obtained in the first aspect of the aforementioned present invention, is provided with an upper electrode and an intermediate electrode in which the characteristics for raising the photoelectric conversion efficiency are individually optimized.

In addition, a method for manufacturing a photovoltaic cell according to the third aspect of the present invention is a method for manufacturing a tandem-type photovoltaic cell in which an upper electrode, a first electricity generating layer, an intermediate electrode, a second electricity generating layer, and a rear electrode are laminated on a substrate, the method including the step of: forming the upper electrode and the intermediate electrode by sputtering using a target that contains a zinc oxide-based material, wherein in the step of forming the upper electrode and the intermediate electrode, the sputtering is performed in an atmosphere in which water vapor and at least one of hydrogen gas and oxygen gas are introduced; and the introduction amount of the water vapor when forming the intermediate electrode is made more than the introduction amount of the water vapor when forming the upper electrode.

According to the aforementioned third aspect of the present invention, the same effect is obtained as the effect that is obtained by the aforementioned second aspect of the invention.

A photovoltaic cell according to a fourth aspect of the present invention is a tandem-type photovoltaic cell in which an upper electrode, a first electricity generating layer, an intermediate electrode, a second electricity generating layer, and a rear electrode are laminated on a substrate, wherein the upper electrode and the intermediate electrode include a zinc oxide-based material; and the amount of oxygen atoms that are contained is more than the amount of oxygen atoms contained in the upper electrode.

According to the aforementioned fourth aspect of the present invention, the same effect is obtained as the effect that is obtained by the aforementioned second aspect of the invention.

It may be arranged such that the resistance of the upper electrode is lower than the resistance of the intermediate electrode; and the light transmittance of the intermediate electrode in the wavelength range of 800 to 1,200 nm is higher than the light transmittance of the upper electrode.

It may be arranged such that the resistance of the upper electrode is 30 Ω/square or less; and the transmittance of the intermediate electrode in the wavelength range of 800 to 1,200 nm is 80% or more.

It may be arranged such that the resistance of the intermediate electrode is 30 Ω/square or more.

### Effect of the Invention

According to the method for manufacturing a photovoltaic cell of the first aspect of the aforementioned present invention, when forming a zinc oxide-based transparent electrically conductive film that constitutes the upper electrode and the intermediate electrode of a photovoltaic cell by a sputtering method, the sputtering is performed in an atmosphere that contains two or three selected from among a group consisting of hydrogen gas, oxygen gas, and water vapor. That is, it is possible to perform formation of a zinc oxide-based transparent electrically conductive film in an atmosphere in which the ratio of the reducing gas to the oxidizing gas is well proportioned. By performing the sputtering in this kind of atmosphere, a transparent electrically conductive film is formed in which the number of oxygen vacancies in the zinc oxide crystal is controlled. As a result, it is possible to obtain a transparent electrically conductive film that has the desired conductivity and surface resistance value.

In addition, according to the aforementioned method for manufacturing a photovoltaic cell, it is possible to obtain a transparent electrically conductive film that does not produce metallic luster. For this reason, it is possible to maintain the transparency of the transparent electrically conductive film with respect to visible light rays.

Accordingly, with the aforementioned method for manufacturing a photovoltaic cell, it is possible to form a zinc oxide-based transparent electrically conductive film that constitutes the upper electrode and the intermediate electrode of a photovoltaic cell in which the surface resistance is low and having excellent transparency with respect to visible light rays. As a result, it is possible to manufacture a photovoltaic cell having an excellent photoelectric conversion efficiency.

In addition, according to the method for manufacturing a photovoltaic cell of the second to fourth aspects and the photovoltaic cell of the aforementioned invention, it is possible to obtain a photovoltaic cell that, in addition to the effect that is obtained in the first aspect of the aforementioned present invention, is provided with an upper electrode and an intermediate electrode in which the characteristics for raising the photoelectric conversion efficiency are individually optimized.

### BRIEF DESCRIPTION OF THE DRAWINGS

FIG. 1 is a schematic configuration drawing that shows the preferred film forming apparatus for the method for manufacturing a photovoltaic cell according to an embodiment of the present invention.

FIG. 2 is a cross-sectional view that shows the preferred film forming apparatus for the method for manufacturing a photovoltaic cell according to the embodiment.

FIG. 3 is a cross-sectional view that shows another example of the film forming apparatus that is used in the method for manufacturing a photovoltaic cell according to the embodiment.

FIG. 4 is a cross-sectional view that shows one example of the photovoltaic cell that is formed by the method for manufacturing a photovoltaic cell according to the embodiment.

FIG. 5 is a graph that shows an example according to the present invention.

FIG. 6 is a graph that shows an example according to the present invention.

FIG. 7 is a graph that shows an example according to the present invention.

FIG. 8 is a graph that shows an example according to the present invention.

FIG. 9 is a graph that shows an example according to the present invention.

FIG. 10 is a graph that shows an example according to the present invention.

FIG. 11 is a graph that shows an example according to the present invention.

FIG. 12 is a graph that shows an example according to the present invention.

### DESCRIPTION OF REFERENCE NUMERALS

50 Photovoltaic cell

51 Glass substrate (Substrate)

53 Upper electrode (Zinc oxide-based transparent electrically conductive film)

57 Intermediate electrode (Zinc oxide-based transparent electrically conductive film)

### BEST MODE FOR CARRYING OUT THE INVENTION

A method for manufacturing a photovoltaic cell according to one embodiment of the present invention shall be described hereinbelow with reference to the drawings. Note that this embodiment is a concrete description for better understanding the gist of the present invention, and unless otherwise stated should not be deemed to limit the present invention.

First, in the method for manufacturing a photovoltaic cell of the present invention, one example of a preferred sputtering apparatus (film forming apparatus) for forming a zinc oxide-based transparent electrically conductive film that constitutes an upper electrode and an intermediate electrode shall be described.

### (Sputtering Apparatus 1)

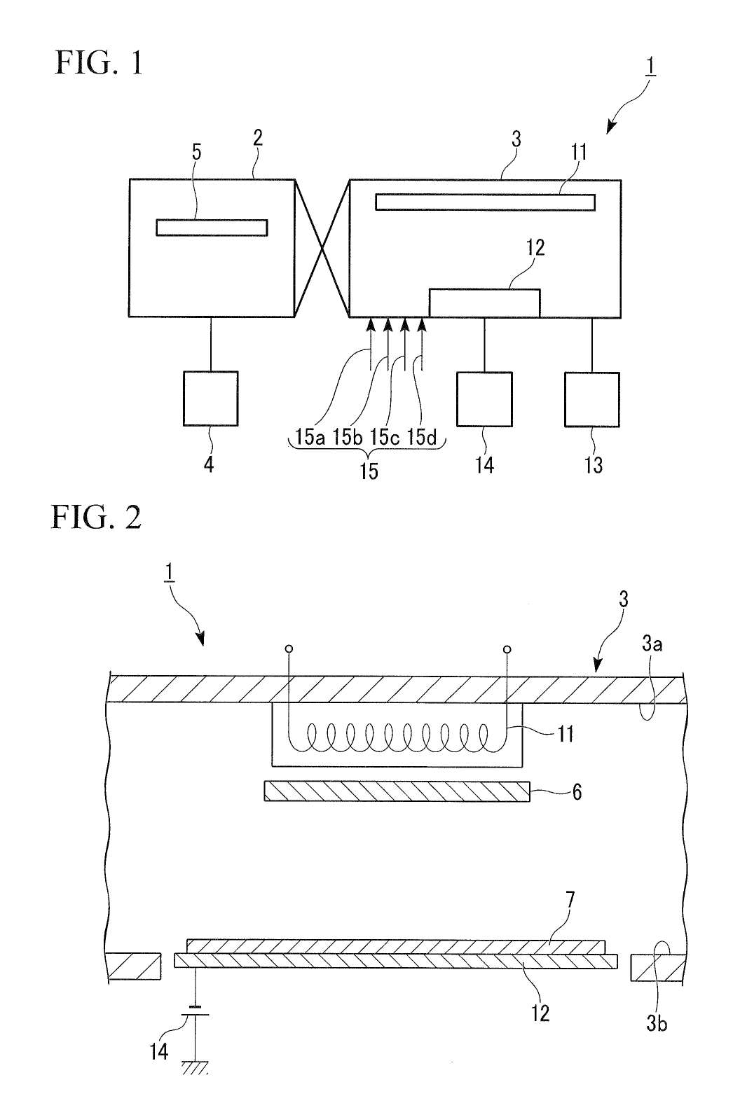

FIG. 1 is a schematic configuration drawing (plan view) that shows the sputtering apparatus (film forming apparatus) according to the present embodiment, and FIG. 2 is a plan cross-sectional view that shows the essential portions of the film forming chamber of the same sputtering apparatus. This sputtering apparatus 1 is an interback-type sputtering apparatus, and is provided with a preparation/ejection chamber 2 that for example carries in/carries out a substrate such as an alkali-free glass substrate (not illustrated) and a film forming chamber (vacuum container) 3 in which a zinc oxide-based transparent electrically conductive film is formed on the substrate.

In the preparation/ejection chamber 2 is provided a rough exhaust means 4 such as a rotary pump or the like that performs rough vacuuming of this chamber. In addition, a substrate tray 5 for holding/moving a substrate is disposed in a movable manner in the chamber of the preparation/ejection chamber 2.

A heater 11 that heats a substrate 6 is provided longitudinally on one side surface 3a of the film forming chamber 3. A target 7 of a zinc oxide-based material is held on the other side surface 3b of the film forming chamber 3, and a sputtering cathode mechanism (target holding means) 12 for applying a desired sputtering voltage is longitudinally provided on this target 7. Moreover, in the film forming chamber 3 are provided a high vacuum exhaust means 13 such as a turbo molecule pump that performs high vacuuming of this chamber, a power supply 14 that impresses a sputtering voltage on the target 7, and a gas introduction means 15 that introduces gas into this chamber.

The sputtering cathode mechanism 12 consists of a plate-shaped metal plate, and the target 7 is fixed by bonding (fixing) with a brazing material or the like.

The power supply 14 is provided with a direct current power supply and a high frequency power supply (not illustrated), and applies a sputtering voltage in which a high-frequency voltage is superimposed on a direct current voltage to the target 7.

The gas introduction means 15 is provided with a sputtering gas introduction means 15a that introduces sputtering gas such as argon, a hydrogen gas introduction means 15b that introduces hydrogen gas, an oxygen gas introduction means 15c that introduces oxygen gas, and a water vapor introduction means 15d that introduces water vapor.

Note that in this gas introduction means 15, the hydrogen gas introduction means 15b, the oxygen gas introduction means 15c that introduces oxygen gas, and the water vapor introduction means 15d are selected as the need arises. For example, two means may be selected and used such as “the hydrogen gas introduction means 15b and the oxygen gas introduction means 15c”, “the hydrogen gas introduction means 15b and the water vapor introduction means 15d”.

### (Sputtering Apparatus 2)

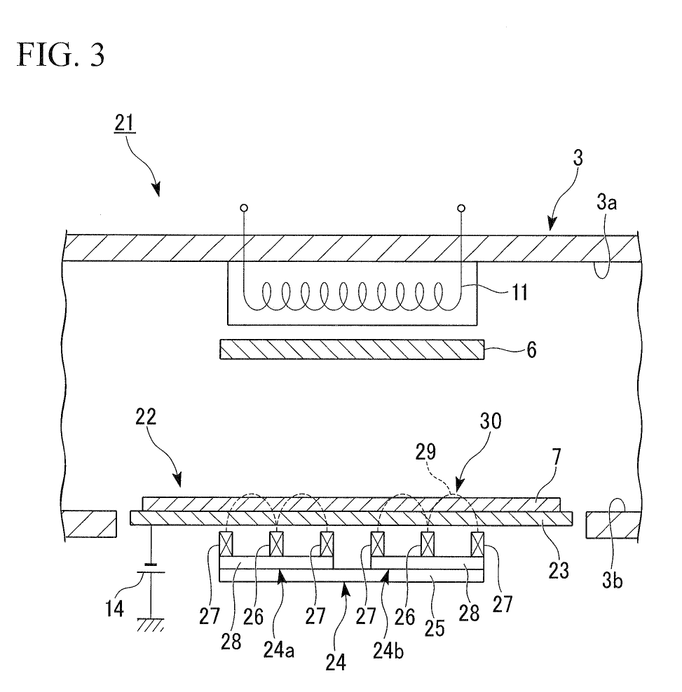

FIG. 3 is a plan cross-sectional view that shows one example of another sputtering apparatus that is used in the method for manufacturing a photovoltaic cell according to the present embodiment, that is, the essential portions of the film forming chamber of an interback-type magnetron sputtering apparatus. The magnetron sputtering apparatus 21 shown in FIG. 3 differs from the sputtering apparatus 1 shown in FIGS. 1 and 2 on the point of a longitude sputtering cathode mechanism (target holding means) 22 that holds the target 7 of a zinc oxide-based material and generates a desired magnetic field being provided on one side surface 3b of the film forming chamber 3.

The sputtering cathode mechanism 22 is provided with a back plate 23 that bonds (fixes) the target 7 with a brazing material or the like, and a magnetic circuit (magnetic field generating means) 24 that is disposed along the rear surface of the back plate 23. This magnetic circuit 24 generates a horizontal magnetic field on the front surface of the target 7. The magnetic circuit 24 is provided a plurality of magnetic circuit units (two in FIG. 3) 24a, 24b, and a bracket 25 that couples and unifies these magnetic circuit units 24a, 24b. These magnetic circuit units 24a, 24b are each provided with a first magnet 26 and a second magnet 27 whose polarities at the surface on the back plate 23 side mutually differ, and a yoke 28 on which they are fitted.

In this magnetic circuit 24, a magnetic field that is expressed by magnetic lines of force 29 is generated by the first magnet 26 and the second magnet 27 whose polarities mutually differ on the back plate 23 side. Thereby, a position 30 appears at which the vertical magnetic field becomes 0 (the horizontal magnetic field is a maximum) at a region corresponding to the space of the first magnet 26 and the second magnet 27 on the surface of the target 7. Since a high density plasma is generated at this position 30, it is possible to improve the film forming speed.

In the film forming apparatus shown in FIG. 3, since the sputtering cathode mechanism 22 that generates a desired magnetic field is longitudinally provided on the one side surface 3b of the film forming chamber 3, it is possible to form a zinc oxide-based transparent electrically conductive film with an organized crystal lattice by making the sputtering voltage 340 V or less and the maximum value of the horizontal magnetic field strength on the surface of the target 7 600 Gauss or more. Oxidation of this zinc oxide-based transparent electrically conductive film is hindered even if annealing is performed at a high temperature after film formation, and it is possible to inhibit increases in the specific resistance thereof. Moreover, it is possible to make a zinc oxide-based transparent electrically conductive film that forms an upper electrode and an intermediate electrode of a photovoltaic cell into one having excellent heat resistance.

### (Photovoltaic Cell)

The photovoltaic cell that is manufactured according to the manufacturing method of the present embodiment is described based on FIG. 3. FIG. 3 is a cross-sectional view that shows one example of the configuration of the photovoltaic cell. A photovoltaic cell 50 is provided with a glass substrate 51 that is provided on the surface, an upper electrode 53 consisting of a zinc oxide-based transparent electrically conductive film that is provided on the glass substrate 51, a top cell 55 that is constituted by amorphous silicon or the like, an intermediate electrode 57 consisting of a transparent electrically conductive film that is provided between the top cell 55 and a bottom cell 59 described below, a bottom cell 59 that is constituted by microcrystal silicon or the like, a buffer layer 61 that consists of a transparent electrically conductive film, and a rear electrode 63 that consists of a metal film, and these are laminated.

That is, the photovoltaic cell 50 is an a-Si/microcrystal silicon tandem-type photovoltaic cell. In this kind of photovoltaic cell 50 having a tandem structure, improvement of the power generation efficiency is accomplished by absorbing short wavelength light with the top cell 55 and long wavelength light with the bottom cell 59. Note that the upper electrode 53 is formed with a film thickness of 200 nm to 1000 nm

The top cell 55 is constituted by the three layers of a p layer (55p), an i layer (55i), and an n layer (55n), and among these, the i layer (55i) is constituted by amorphous silicon. In addition, the bottom cell 59, similarly to the top cell 55, is constituted by the three layers of p layer (59p), an i layer (59i), and an n layer (59n), and among these, the i layer (59i) is constituted by microcrystal silicon.

In the photovoltaic cell 50 of this type of constitution, when energy particles called photons that are contained in sunlight hit the i layer, due to the photovoltaic effect, an electron and a hole is produced, with the electron moving toward the n layer and the hole moving toward the p layer. The electrons that are generated by this photovoltaic effect are extracted by the upper electrode 53 and the rear electrode 63, and as a result, light energy is converted to electrical energy.

In addition, since the intermediate electrode 57 is provided between the top cell 55 and the bottom cell 59, a portion of the light that passes through the top cell 55 and reaches the bottom cell 59 is reflected by the intermediate electrode 57 and again enters the top cell 55 side. Thereby, the sensitivity characteristic of the cell improves, and as a result, the power generation efficiency is elevated.

Moreover, the sunlight that has entered from the glass substrate 51 side passes through each layer, and is reflected by the rear electrode 63. In order to improve the conversion efficiency of the light energy, a texture structure is adopted for photovoltaic cell 50 with the object of the prism effect of extending the optical path of sunlight that has entered the upper electrode 53 and a confinement effect of light.

The upper electrode 53 and the intermediate electrode 57 of the photovoltaic cell 50 according to the present embodiment are constituted by a zinc oxide-based film (transparent electrically conductive film) that is manufactured using the sputtering apparatus 1 shown in FIGS. 1 and 2.

In the upper electrode 53 and the intermediate electrode 57, a property that passes light to be absorbed by the I layer and electrical conductivity for extracting the electrons produced by the photovoltaic power are required. That is, in the upper electrode 53 and the intermediate electrode 57, it is sought to achieve lowness of the specific resistance and highness of the light transmittance. Using the sputtering apparatus according to the present embodiment, by performing sputtering in an atmosphere that includes two or three selected from among a group of hydrogen gas, oxygen gas, and water vapor, it is possible to achieve a transparent electrically conductive film in which, even in particularly in zinc oxide-based films, especially the specific resistance is low, and the light transmittance is high in the visible light region. Thereby, it is possible to achieve a photovoltaic cell 50 that has excellent photoelectric conversion efficiency.

Note that in the case of forming the intermediate electrode 57 by a magnetron sputtering apparatus, there is the risk of damage occurring in the top cell 55 that is a foundation due to negative ions that are excited by the plasma being accelerated and charging into the substrate. In addition, in the case of forming the buffer layer 61, there is the risk of damage occurring in the bottom cell 59 that similarly serves as a foundation.

Therefore, it is preferable to form the intermediate electrode 57 and the buffer 61 while suppressing damage to the foundation. Further, there is the aim of attempting to prevent the diffusion of the metal film that is used in the rear electrode 63.

### (Method for Manufacturing Photovoltaic Cell)

Next, as an example of the method for manufacturing the photovoltaic cell according to the present embodiment, a method of forming a zinc oxide-based transparent electrically conductive film that constitutes the upper electrode and the intermediate electrode of a photovoltaic cell is shown, using the sputtering apparatus 1 shown in FIGS. 1 and 2.

First, the target 7 is fixed to the sputtering cathode mechanism 12 by bonding with a brazing material or the like. Here, a zinc oxide-based material, for example aluminum-doped zinc oxide (AZO) in which aluminum (Al) is added in an amount of 0.1 to 10 percent by weight, and gallium-doped zinc oxide (GZO) in which gallium (Ga) is added in an amount of 0.1 to 10 percent by weight, is used in the target material. Among these, aluminum-doped zinc oxide (AZO) is preferred on the point of being capable of forming a thin film with a lower specific resistance.

Next, the substrate that consists of for example glass (glass substrate) 6 is stored on the substrate tray 5 of the preparation/ejection chamber 2, and the preparation/ejection chamber 2 and the film forming chamber 3 are pumped to a rough vacuum by the rough exhaust means 4 until reaching a predetermined degree of vacuum, for example 0.27 Pa (2.0×10⁻³ Torr). Then, the substrate 6 is carried into the film forming chamber 3 from the preparation/ejection chamber 2, and this substrate 6 is disposed in front of the heater 11, which is in the state of the setting being OFF, so as to face the target 7. The substrate 6 is heated by the heater 11 so as to be in a temperature range of 100° C. to 600° C.

Next, the film forming chamber 3 is pumped to a high vacuum by the high vacuum exhaust means 13 until reaching a predetermined high degree of vacuum, for example, 2.7×10⁻⁴ Pa (2.0×10⁻⁶ Torr). Then, sputtering gas such as Ar or the like is introduced to the film forming chamber 3 by the sputtering gas introduction means 15a, and two or three of gases that are selected from the group of hydrogen gas, oxygen gas, and water vapor are introduced using at least two among the hydrogen gas introduction means 15b, the oxygen gas introduction means 15c that introduces oxygen gas, and the water vapor introduction means 15d.

Here, in the case of having selected hydrogen gas and oxygen gas, it is preferable that the ratio R (P_{H2}/P_{O2}) of the partial pressure of hydrogen gas (P_{H2}) and the partial pressure of oxygen gas (P_{O2}) satisfies

R=P_{H2}/P_{O2}≧2 (3)

Thereby, the atmosphere in the film forming chamber 3 becomes a reactive gas atmosphere in which the hydrogen gas density is 2 times or more the oxygen gas density. By satisfying R=P_{H2}/P_{O2}≧2, it is possible to obtain a transparent electrically conductive film with a specific resistance of 2000 μΩ·cm or less is obtained. It is preferable for the upper electrode 53 and the intermediate electrode 57 of the photovoltaic cell 50 to have a specific resistance of 2000 μω·cm or less.

Next, a sputtering voltage is applied to the target 7 with the power supply 14. For example, a sputtering voltage that consists of a high-frequency voltage superimposed on a direct current voltage is applied to the target 7. By the application of the sputtering voltage, plasma is generated on the substrate 6, and ions of the sputtering gas such as Ar that are excided by this plasma collide with the target 7. As a result of this collision, the atoms that constitute the zinc oxide-based material such as aluminum-doped zinc oxide (AZO) and gallium-doped zinc oxide (GZO) fly out from the target 7, and form a transparent electrically conductive film that consists of the zinc oxide-based material on the substrate 6.

In this film forming process, since the hydrogen gas density becomes five times or more the oxygen gas density in the film forming chamber 3, a reactive gas atmosphere results in which the ratio of the hydrogen gas and the oxygen gas is balanced. It is possible to obtain a transparent electrically conductive film in which the number of oxygen vacancies in the zinc oxide crystal is controlled by sputtering that is performed in this reactive gas atmosphere. As a result, since the specific resistance thereof also declines to be equivalent to that of an ITO film, it is possible to obtain a transparent electrically conductive film that has the desired electrical conductivity and specific resistance value. Moreover, there is no metallic luster in the obtained transparent electrically conductive film, and the transparency with respect to visible light rays is maintained.

Next, this substrate 6 is transported from the film forming chamber 3 to the preparation/ejection chamber 2, the vacuum of the preparation/ejection chamber 2 is broken, and the substrate 6 on which this zinc oxide-based transparent electrically conductive film is formed is taken out.

In this manner, the substrate 6 is obtained on which a zinc oxide-based transparent electrically conductive film is formed having low specific resistance and good transparency with respect to visible light rays. By using this substrate 6 in a photovoltaic cell, it is possible to obtain a photovoltaic cell that has an upper electrode and an intermediate electrode with a low specific resistance and high transparency with respect to visible light rays. That is, even with a zinc-oxide based transparent electrically conductive film that can be produced at a low cost, it is possible to improve the photoelectric conversion efficiency of the photovoltaic cell.

Moreover, by changing the introduction amount of the oxygen gas or the water vapor to the film forming chamber in the aforementioned film formation process, it is possible to adjust the balance between the transmittance of light in the long wavelength region and the resistance of the obtained transparent electrically conductive film. By using a transparent electrically conductive film that is formed in an atmosphere in which the introduction amount of oxygen gas is comparatively more and a transparent electrically conductive film that is formed in an atmosphere in which the introduction amount of oxygen gas is comparatively less for the intermediate electrode and the upper electrode, respectively, of a photovoltaic cell, it is possible to obtain a photovoltaic cell that is provided with an intermediate electrode in which the transmittance of light in the long wavelength region is higher than the upper electrode with lower resistance.

In this case, in the upper electrode, the recovery efficiency of electrical energy that is converted from light improves, and in the intermediate electrode, the transmittance of light in the long wavelength region that has passed through the top cell improves. As a result, it becomes possible to further improve the photoelectric conversion efficiency of a photovoltaic cell.

### EXAMPLES

Hereinbelow, the experimental results are enumerated for the formation of zinc oxide-based transparent electrically conductive film that constitutes the upper electrode and the intermediate electrode, in relation to the method for manufacturing the photovoltaic cell of the present invention.

### Example 1

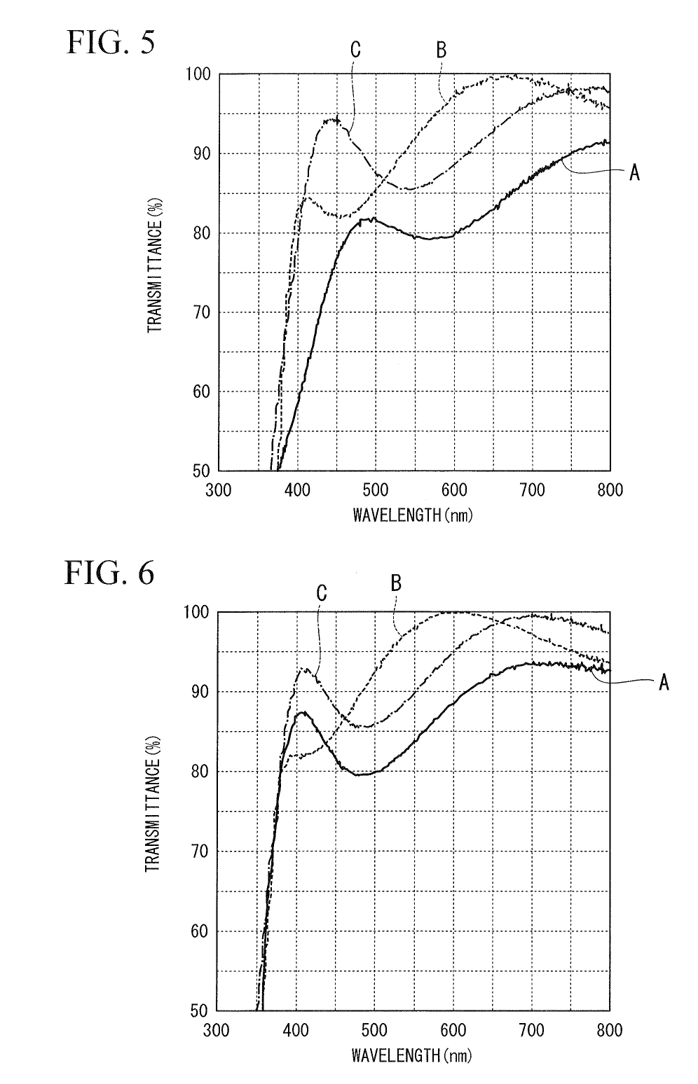

FIG. 5 is a graph that shows the effect of H₂O gas (water vapor) in non-thermal film formation. In FIG. 5, A denotes the transmittance of a zinc oxide-based transparent electrically conductive film in the case of not introducing a reactive gas, B denotes the transmittance of a zinc oxide-based transparent electrically conductive film in the case of introducing H₂O gas so that the partial pressure thereof becomes 5×10⁻⁵ Torr, and C denotes the transmittance of a zinc oxide-based transparent electrically conductive film in the case of introducing O₂ gas so that the partial pressure thereof becomes 1×10⁻⁵ Torr. Note that a parallel plate-type cathode that applies a direct current (DC) voltage was used.

In the case of not introducing a reactive gas, the film thickness of the transparent electrically conductive film was 207.9 nm, and the specific resistance was 1576 μΩ·cm.

In addition, in the case of introducing H₂O gas, the film thickness of the transparent electrically conductive film was 204.0 nm, and the specific resistance was 64464 μΩ·cm.

Further, in the case of introducing O₂ gas, the film thickness of the transparent electrically conductive film was 208.5 nm, and the specific resistance was 2406 μΩ·cm.

According to the experimental result shown in FIG. 5, it was found that it is possible to change the peak wavelength of transmittance without changing the film thickness by introducing H₂O gas. In addition, compared to the case of A in which reactive gas is not introduced, in case B in which H₂O gas is introduced, the transmittance is also totally improved.

In addition, in the case of introducing H₂O gas, the specific resistance is high, and the resistance degradation increases, but the transmittance is high. That is, it was found that the transparent electrically conductive film that is obtained in this case can be applied to electrodes of a photovoltaic cell in which the requirement for comparatively low resistance is weak since the electrode area is large, and the requirement for transmittance is strong, and optical members in which resistance mostly does not become a problem.

Moreover, it was found that by repeatedly performing film formation with the condition of changing between the non-introduction and introduction of H₂O gas, or the introduction amount, an optical disc with a laminated structure in which the refractive index changes for each layer is obtained with one target.

In the case of wanting to selectively making light of a wavelength with a good luminous efficiency penetrate the upper electrode and the intermediate electrode of the photovoltaic cell, it is possible to create a photovoltaic cell with a good efficiency by making the peak of the wavelength that penetrates the upper electrode match the wavelength of the light that is selected.

By introducing H₂O gas, in addition to raising the transmittance, it is possible to selectively raise the transmittance of light having a desired frequency.

### Example 2

FIG. 6 is a graph that shows the effect of H₂O gas (water vapor) in thermal film formation in which the reference temperature is assumed to be 250° C. In FIG. 6, A denotes the transmittance of a zinc oxide-based transparent electrically conductive film in the case of not introducing a reactive gas, B denotes the transmittance of a zinc oxide-based transparent electrically conductive film in the case of introducing H₂O gas so that the partial pressure thereof becomes 5×10⁻⁵ Torr, and C denotes the transmittance of a zinc oxide-based transparent electrically conductive film in the case of introducing O₂ gas so that the partial pressure thereof becomes 1×10⁻⁵ Torr. Note that a parallel plate-type cathode that applies a direct current (DC) voltage was used.

In the case of not introducing a reactive gas, the film thickness of the transparent electrically conductive film was 201.6 nm, and the specific resistance was 766 μΩ·cm.

Moreover, in the case of introducing H₂O gas, the film thickness of the transparent electrically conductive film was 183.0 nm, and the specific resistance was 6625 μΩ·cm.

Further, in the case of introducing O₂ gas, the film thickness of the transparent electrically conductive film was 197.3 nm, and the specific resistance was 2214 μΩ·cm.

According to the experimental result shown in FIG. 6, in the case of introducing H₂O gas, although the film thickness became somewhat thinner, the peak wavelength shifted by an amount equal to or greater than the shift of the peak wavelength due to the interference of the film thickness. That is, it was found that even for the case of raising the substrate temperature to 250° C., the same effect as the case of not applying heat is obtained.

### Example 3

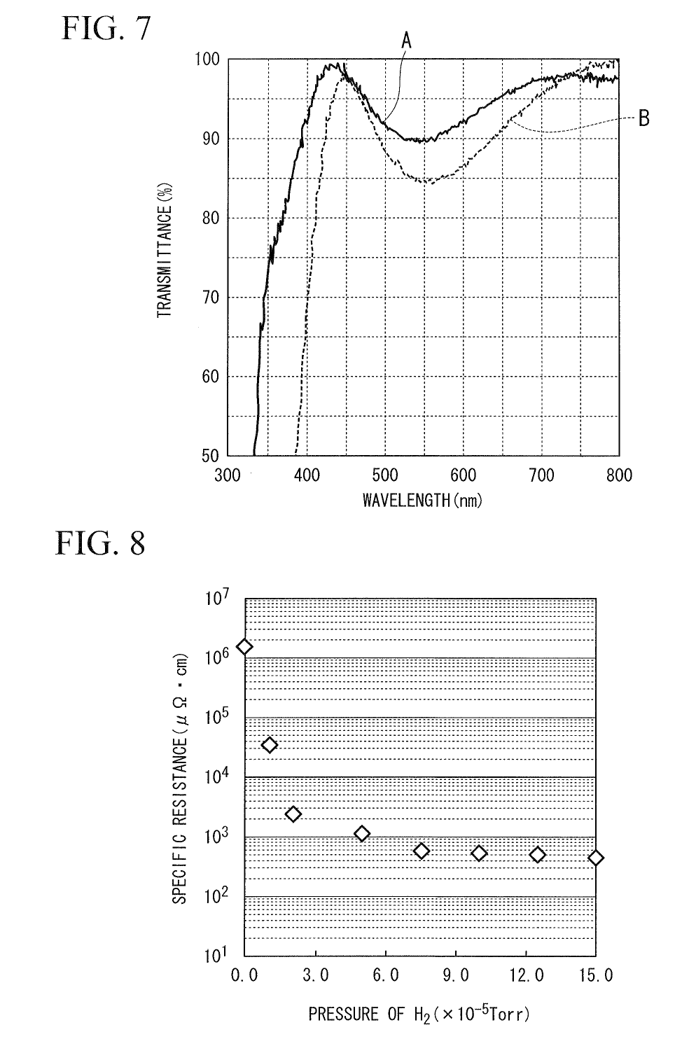

FIG. 7 is a graph that shows the effect in the case of simultaneously introducing H₂ gas and O₂ gas during thermal film forming in which the substrate temperature has been raised to 250° C. In FIG. 7, A denotes the transmittance of a zinc oxide-based transparent electrically conductive film in the case of simultaneously introducing H₂ gas and O₂ gas so that the partial pressure of the H₂ gas becomes 15×10⁻⁵ Torr and the partial pressure of the O₂ gas becomes 1×10⁻⁵ Torr, and B denotes the transmittance of a zinc oxide-based transparent electrically conductive film in the case of introducing O₂ gas so that the partial pressure thereof becomes 1×10⁻⁵ Torr. Note that a parallel plate-type cathode that is capable of superimposing a high frequency (RF) voltage on a direct current (DC) voltage is used.

In the case of simultaneously introducing H₂ gas and O₂ gas, the film thickness of the transparent electrically conductive film was 211.1 nm.

In addition, in the case of introducing O₂ gas only, the film thickness of the transparent electrically conductive film was 208.9 nm.

According to the experimental result shown in FIG. 7, it was found that in the case of simultaneously introducing H₂ gas and O₂ gas, the peak wavelength shifted by an amount equal to or greater than the shift of the peak wavelength due to the interference of the film thickness, compared to case of introducing only O₂ gas. There was also found to be an improvement in the transmittance compared to the case of introducing only O₂ gas.

### Example 4

FIG. 8 is a graph that shows the effect in the case of simultaneously introducing H₂ gas and O₂ gas during thermal film forming in which the substrate temperature has been raised to 250° C. It shows the specific resistance of a zinc oxide-based transparent electrically conductive film in the case of the partial pressure of the O₂ gas being fixed at 1×10⁻⁵ Torr (partial pressure of flow conversion), and the partial pressure of the H₂ gas being altered between 0 to 15×10⁻⁵ Torr. Note that a parallel plate-type cathode that is capable of superimposing a high frequency (RF) voltage on a direct current (DC) voltage is used. In addition, note that the film thickness of the obtained transparent electrically conductive film was mostly 200 nm.

According to the experimental result shown in FIG. 8, although the specific resistance rapidly decreased in the range of the partial pressure of the H₂ gas from 0 Torr to 2.0 Torr, the specific resistance was found to become stable when the partial pressure of the H₂ gas exceeded 2.0 Torr. Since the specific resistance of the transparent electrically conductive film in the case of not introducing a reactive gas under the same conditions is 422 μΩ·cm, in the case of simultaneously introducing H₂ gas and O₂ gas, it was found that the degradation in the specific resistance was small.

In particular, in a transparent electrically conductive film to be used in the upper electrode and intermediate electrode of a photovoltaic cell, in addition to the transmittance in the visible light region being high, low resistance is also required. That of 2,000 μΩ·cm or less is required in ordinary transparent electrodes. In FIG. 6, the specific resistance is 2,000 μΩ·cm or less when the pressure of H₂ gas is 2.0×10⁻⁵ Torr or more. Since the O₂ gas pressure is 1×10⁻⁵ Torr, in order to make the specific resistance 2,000 μΩ·cm or less, it is preferable to have R=P_{H2}/P_{O2}≧2.

### Example 5

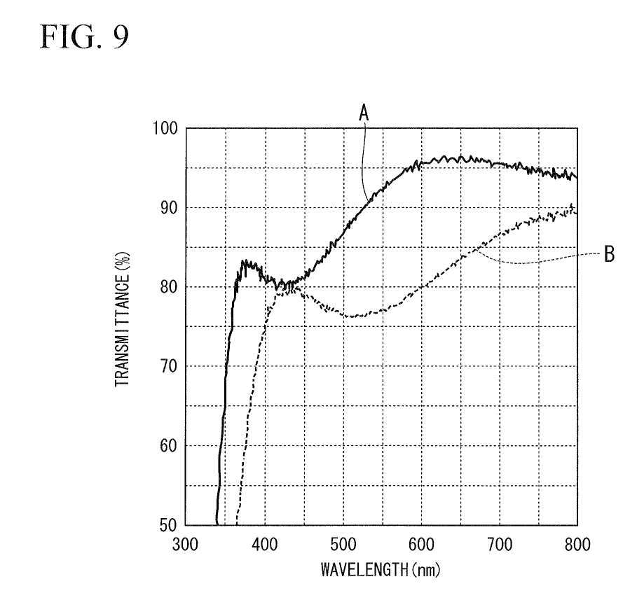

FIG. 9 is a graph that shows the effect of H₂ gas in non-thermal film formation. In FIG. 9, A denotes the transmittance of a zinc oxide-based transparent electrically conductive film in the case of introducing H₂ gas so that the partial pressure thereof becomes 3×10⁻⁵ Torr and B denotes the transmittance of a zinc oxide-based transparent electrically conductive film in the case of introducing O₂ gas so that the partial pressure thereof becomes 1.125×10⁻⁵ Torr. Note that a facing-type cathode that applies a direct current (DC) voltage was used.

In the case of introducing H₂ gas, the film thickness of the transparent electrically conductive film was 191.5 nm, and the specific resistance was 913 μΩ·cm.

In addition, in the case of introducing O₂ gas, the film thickness of the transparent electrically conductive film was 206.4 nm, and the specific resistance was 3608 μΩ·cm.

According to the experimental result shown in FIG. 9, it was found that it is possible to change the peak wavelength of transmittance without changing the film thickness by introducing H₂ gas. In addition, it was found that the transmittance in the case of having introduced H₂ gas is high compared to the case of having introduced O₂ gas. From the above, it was found that a zinc oxide-based transparent electrically conductive film with a high transmittance and low specific resistance is obtained by optimizing the H₂ gas introduction amount in the process that introduced the H₂ gas.

From the experimental result, it was found that it is possible to significantly change the shift amount of the peak by the introduction of water vapor. That is, according to the above experimental result, in the case of wanting to change the peak wavelength of transmittance, introducing water vapor is effective.

Moreover, adjustment of the shift amount is also possible by the introduction of oxygen or hydrogen.

### Example 6

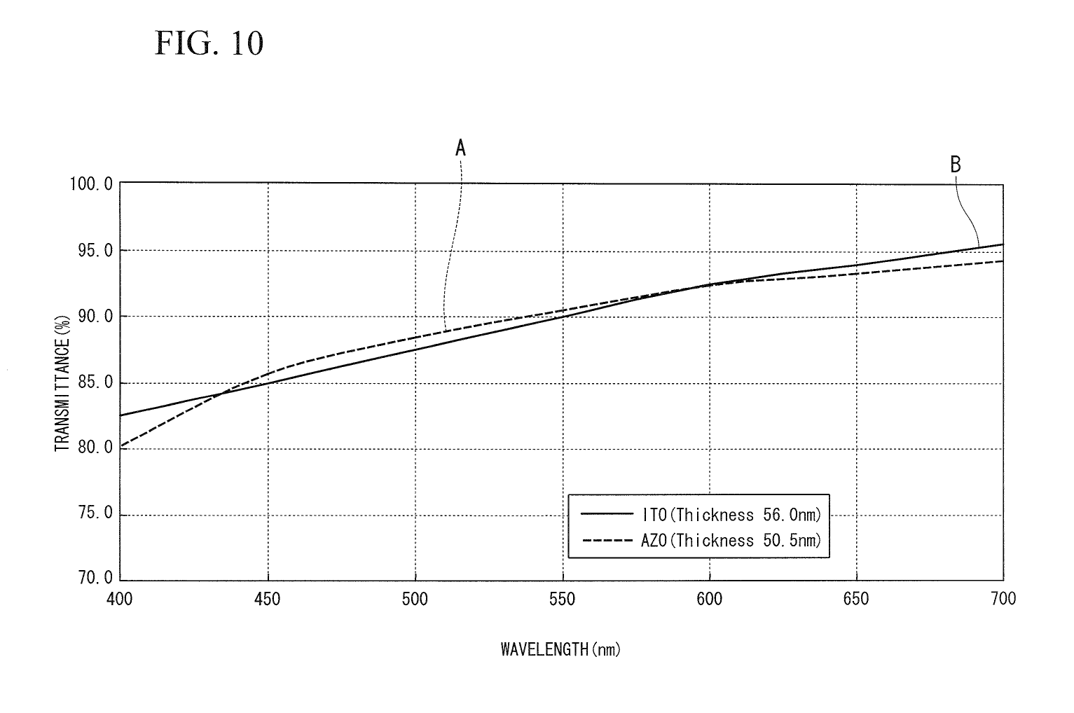

FIG. 10 is a graph that shows the result of measuring the transmittance of light in the wavelength range of 400 to 700 nm, for a substrate on which is formed an ITO film and a substrate on which is formed an AZO film. In FIG. 10, A denotes a substrate with an AZO film formed to a thickness of 50.5 nm, and B denotes a substrate with an ITO film formed to a thickness of 56.0 nm.

According to the experimental result shown in FIG. 10, it was confirmed that in the wavelength range of 400 to 700 nm, the respective transmittances of a substrate on which a conventional ITO film is formed and a substrate on which the AZO film of the present invention is formed hardly differ.

### Example 7

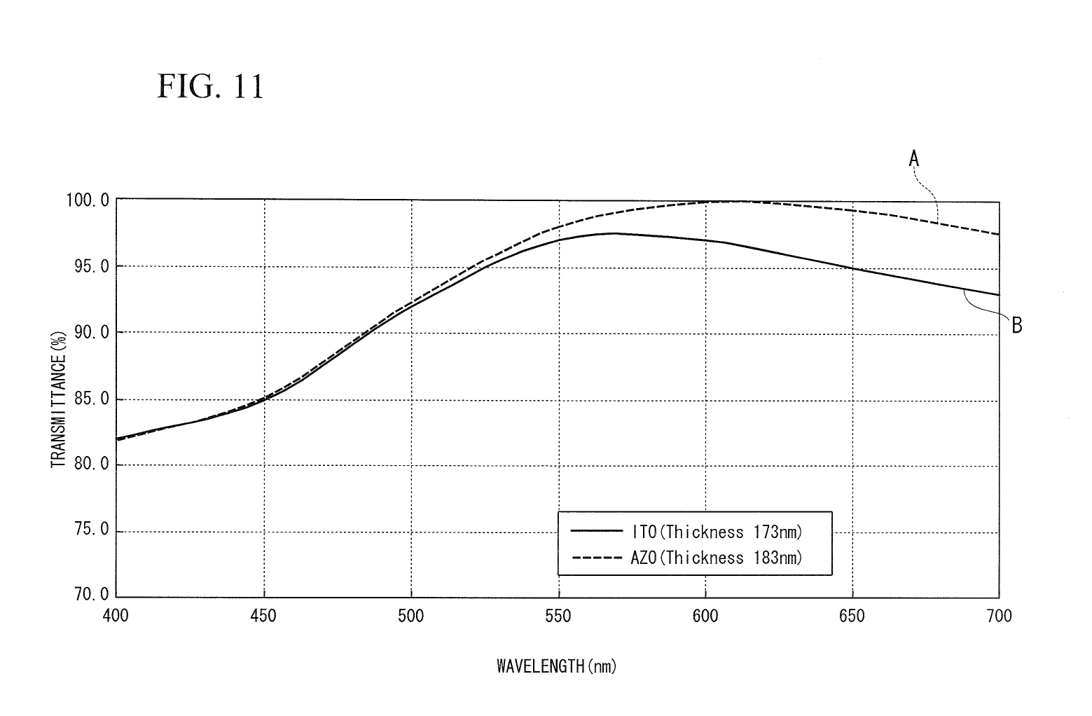

FIG. 11 is a graph that shows the result of measuring the transmittance of light in the wavelength range of 400 to 700 nm, for a substrate on which is formed an ITO film and a substrate on which is formed an AZO film. In FIG. 11, A denotes a substrate with an AZO film formed to a thickness of 183.0 nm, and B denotes a substrate with an ITO film formed to a thickness of 173.0 nm.

According to the experimental result shown in FIG. 11, it was confirmed that in the wavelength range of 400 to 500 nm, the respective transmittances of a substrate on which a conventional ITO film is formed and a substrate on which the AZO film of the present invention is formed hardly differ. In addition, in the wavelength range of 400 to 700 nm, the substrate on which the AZO film of the present invention is formed was found to have better transmittance than the substrate on which a conventional ITO film is formed.

### Example 8

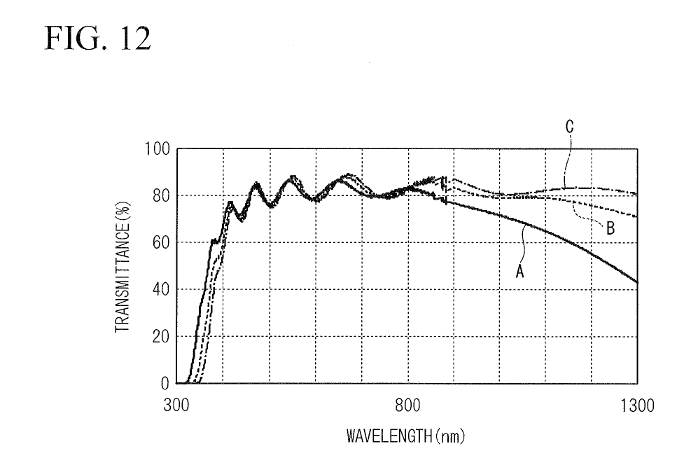

FIG. 12 is a graph that shows the effect of O₂ gas in non-thermal film formation. In FIG. 12, A denotes the transmittance of a zinc oxide-based transparent electrically conductive film in the case of not introducing O₂ gas, B denotes the transmittance of a zinc oxide-based transparent electrically conductive film in the case of introducing O₂ gas so that the partial pressure thereof becomes 2×10⁻⁵ Torr and C denotes the transmittance of a zinc oxide-based transparent electrically conductive film in the case of introducing O₂ gas so that the partial pressure thereof becomes 3×10⁻⁵ Torr. Note that in each of the cases A, B, and C, H₂ gas is introduced so that the partial pressure thereof becomes 3×10⁻⁵ Torr. Note that a facing-type cathode that applies a direct current (DC) voltage was used. The thickness of the obtained transparent electrically conductive film was mostly 700 nm.

In the case of not introducing O₂ gas, the surface resistance value of the transparent electrically conductive film was 4.3 Ω/square, and the specific resistance was 320 μΩ·cm.

In addition, in the case of introducing O₂ gas so that the partial pressure thereof becomes 2×10⁻⁵ Torr, the surface resistance value of the transparent electrically conductive film was 12 Ω/square, and the specific resistance was 850 μΩ·cm.

Further, in the case of introducing O₂ gas so that the partial pressure thereof becomes 3×10⁻⁵ Torr, the surface resistance value of the transparent electrically conductive film was 33 Ω/square, and the specific resistance was 2300 μΩ·cm.

According to the result shown in FIG. 12, it was found that when the partial pressure of the O₂ gas is raised while the partial pressure of the H₂ gas held constant, the transmittance of light in the long wavelength region (for example, 800 to 1300 nm) of the obtained transparent electrically conductive film increases, and the surface resistance and the specific resistance thereof also increase. That is, it was found possible to suitably adjust the balance between the transmittance of light in the long wavelength region and resistance by changing the introduction amount of the O₂ gas.

As stated above, in a transparent electrically conductive film that is used for the upper electrode and the intermediate electrode of a photovoltaic cell, in addition to the transmittance in the visible light region being high, low resistance is also required. Under those requirements, it is desired that the resistance be low particularly in the upper electrode. This is because in the upper electrode, electron transport in the in-plane direction parallel to the formation surface thereof is particularly important.

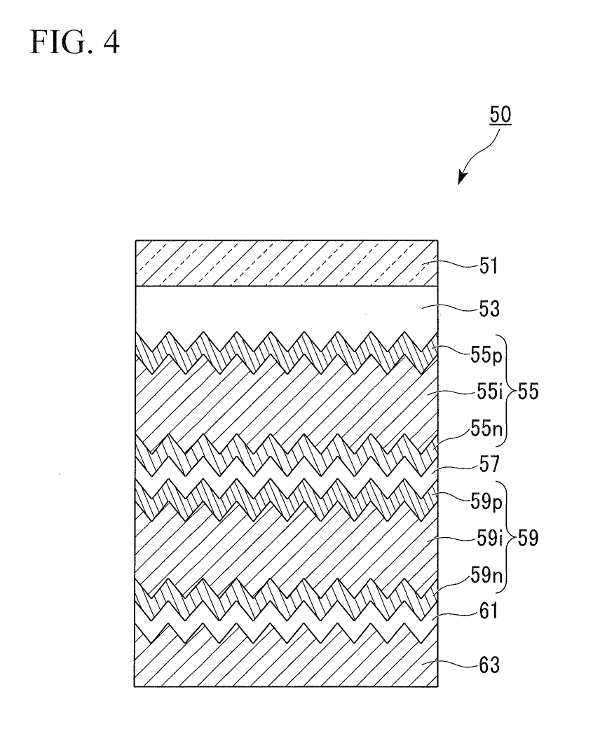

On the other hand, in the intermediate electrode, high transmittance of light particularly in the long wavelength region is sought. This is because, in a tandem-type photovoltaic cell as shown in FIG. 4, conversion of light in the shirt wavelength region is mainly performed in the top cell 55, and conversion of light in the long wavelength region is mainly performed in the bottom cell 59.

By the examples, an upper electrode in which the resistance is still lower and an intermediate electrode in which the transmittance of light in the long wavelength region is still higher are found to be obtained by making the introduction amount of O₂ gas when forming a transparent electrically conductive film to be used for the intermediate electrode more than the introduction amount of O₂ gas when forming a transparent electrically conductive film to be used for the upper electrode.

Note that in the aforementioned Example 8, it is possible to adjust the balance between the resistance of the transparent electrically conductive film and the transmittance of light in the long wavelength region by changing the introduction amount of O₂ gas, but for example, it is possible to adjust the balance even by changing the introduction amount of H₂O gas. This is because the balance between the resistance of the transparent electrically conductive film and the transmittance of light in the long wavelength region is due to the addition amount of oxygen atoms during film formation.

### INDUSTRIAL APPLICABILITY

The present invention can provide a method for manufacturing a photovoltaic cell that lowers the surface resistance of a transparent electrically conductive film that is formed using a zinc oxide-based material and constitutes the upper electrode and intermediate electrode of a photovoltaic cell, favorably maintains transmittance of visible light rays, and improves the photoelectric conversion efficiency.

1. A method for manufacturing a photovoltaic cell that is provided with an upper electrode that is arranged on the light incoming side and functions as a power extraction electrode, the method comprising the step of:
forming the upper electrode on a substrate by sputtering using a target that contains a zinc oxide-based material, wherein
in the step of forming the upper electrode, the sputtering is performed in an atmosphere that contains two or three selected from a group consisting of hydrogen gas, oxygen gas, and water vapor.

2. The method for manufacturing a photovoltaic cell according to claim 1, wherein, in the case of including at least the hydrogen gas and the oxygen gas in the atmosphere when performing the sputtering, a ratio R (P_{H2}/P_{O2}) of the partial pressure of the hydrogen gas (P_{H2}) to the partial pressure of the oxygen gas (P_{O2}) satisfies Equation (1) below.
R=P_{H2}/P_{O2}≧2 (1)

3. The method for manufacturing a photovoltaic cell according to claim 1, wherein the sputtering voltage that is applied to the target is 340 V or less when performing the sputtering.

4. The method for manufacturing a photovoltaic cell according to claim 1, wherein a sputtering voltage composed of a high frequency voltage superimposed on a direct current voltage is applied to the target when performing the sputtering.

5. The method for manufacturing a photovoltaic cell according to claim 1, wherein the maximum value of the strength of the horizontal magnetic field at the surface of the target when performing the sputtering is 600 Gauss or more.

6. The method for manufacturing a photovoltaic cell according to claim 1, wherein the zinc oxide-based material is aluminum-doped zinc oxide or gallium-doped zinc oxide.

7. A method for manufacturing a tandem-type photovoltaic cell in which an upper electrode, a first electricity generating layer, an intermediate electrode, a second electricity generating layer, and a rear electrode are laminated on a substrate, the method comprising the step of:
forming the upper electrode and the intermediate electrode by sputtering using a target that contains a zinc oxide-based material, wherein
in the step of forming the upper electrode and the intermediate electrode, the sputtering is performed in an atmosphere in which at least one of hydrogen gas and water vapor, and oxygen gas are introduced; and
the introduction amount of the oxygen gas when forming the intermediate electrode is made more than the introduction amount of the oxygen gas when forming the upper electrode.

8. A method for manufacturing a tandem-type photovoltaic cell in which an upper electrode, a first electricity generating layer, an intermediate electrode, a second electricity generating layer, and a rear electrode are laminated on a substrate, the method comprising the step of:
forming the upper electrode and the intermediate electrode by sputtering using a target that contains a zinc oxide-based material, wherein
in the step of forming the upper electrode and the intermediate electrode, the sputtering is performed in an atmosphere in which water vapor and at least one of hydrogen gas and oxygen gas are introduced; and
the introduction amount of the water vapor when forming the intermediate electrode is made more than the introduction amount of the water vapor when forming the upper electrode.

9. A tandem-type photovoltaic cell in which an upper electrode, a first electricity generating layer, an intermediate electrode, a second electricity generating layer, and a rear electrode are laminated on a substrate, wherein
the upper electrode and the intermediate electrode include a zinc oxide-based material; and
the amount of oxygen atoms that are contained is more than the amount of oxygen atoms contained in the upper electrode.

10. The photovoltaic cell according to claim 9, wherein
the resistance of the upper electrode is lower than the resistance of the intermediate electrode; and
the light transmittance of the intermediate electrode in the wavelength range of 800 to 1,200 nm is higher than the light transmittance of the upper electrode.

11. The photovoltaic cell according to claim 10, wherein
the resistance of the upper electrode is 30 Ω/square or less; and
the transmittance of the intermediate electrode in the wavelength range of 800 to 1,200 nm is 80% or more.

12. The photovoltaic cell according to claim 11, wherein the resistance of the intermediate electrode is 30 Ω/square or more.
